(19) United States
(12) Patent Application Publication
(10) Pub. No.: US 2026/0242215 A1
(43) Pub. Date: Aug. 20, 2026

(54) MANUFACTURING PROCESS OF A MICROELECTROMECHANICAL SYSTEM WITH MULTIPLE CAVITIES AT DIFFERENT PRESSURES AND RELATED MICROELECTROMECHANICAL SYSTEM

(71) Applicant: STMicroelectronics International N.V., Geneva (CH)

(72) Inventors: Andrea NOMELLINI, Milano (IT); Federico VERCESI, Milano (IT); Riccardo GIANOLA, Bergamo (IT); Matteo BIRONDI, Bergamo (IT)

(73) Assignee: STMicroelectronics International N.V., Geneva (CH)

(21) Appl. No.: 19/543,362

(22) Filed: Feb. 18, 2026

(30) Foreign Application Priority Data
Feb. 20, 2025 (IT) 102025000003309

(51) Int. Cl. B81C 1/00; B81B 7/00

(52) U.S. Cl. CPC B81C 1/00285; B81B 7/0038; B81B 2201/0235; B81B 2201/0242; B81B 2203/0315; B81B 2203/0338; B81C 2201/0176; B81C 2201/0181; B81C 2201/019; B81C 2203/019; B81C 2203/037

(57) ABSTRACT

Process for manufacturing a microelectromechanical system starting from a first semiconductive wafer including a semiconductive substrate, a semiconductive region, and an interposed dielectric region. The process includes forming first and second cavities in the semiconductive region; forming a first channel through the semiconductive region to the dielectric region, and selectively removing the dielectric region to create an intermediate chamber. The first wafer is coupled to a second semiconductive wafer, where first and second microelectromechanical structures are formed, creating first and second chambers. The second chamber is hermetically closed. A transversal channel connects the first chamber, first channel, and intermediate chamber. Second channels are formed through the substrate to the intermediate chamber, allowing communication with the outside. The pressure in the first chamber is set, and the second channels are hermetically closed, sealing the first chamber, transversal channel, first channel, and intermediate chamber.

### PRIORITY CLAIM

This application claims the priority benefit of Italian Application for Patent No. 102025000003309 filed on February 20, 2025, the content of which is hereby incorporated by reference in its entirety to the maximum extent allowable by law.

### TECHNICAL FIELD

The present invention relates to an improved manufacturing process for a microelectromechanical system with multiple cavities at different pressures and to the related microelectromechanical system.

### BACKGROUND

As is known, in many applications, microelectromechanical devices are used that are embedded and sealed in the same package. For example, it is common to integrate uniaxial or multiaxial gyroscopes and accelerometers in the same package.

A frequent issue is that the devices may have optimal operating conditions that are very different from each other, as in the case of gyroscopes and accelerometers. In fact, in order to reduce consumption due to air friction damping, it is preferable to make the gyroscopes work in an environment with relatively low pressure, typically between 0.1 mbar and 1 mbar. Gyroscopes are constantly maintained in resonant oscillation, and low-pressure conditions favor the maintenance of oscillations, reducing damping and dissipated energy. Accelerometers, on the other hand, normally operate in conditions of higher pressure, for example between 1 mbar and a few atmospheres. Similar issues may also arise with other types of devices operating under different conditions, for example, resonators or wake-up systems in combination with gyroscopes or accelerometers.

A possible solution consists of including different devices in the same cavity or chamber of the package, wherein a pressure level is present corresponding to a trade-off between the preferred operating pressures. Solutions of this type are relatively simple to implement but may not be satisfactory and can affect performance.

According to a different solution, the microelectromechanical devices are included in respective sealed and non-communicating chambers. In practice, the devices, for example gyroscopes and accelerometers, are manufactured in a first wafer, while, in a second wafer, caps are provided and cavities are formed in positions corresponding to respective devices. In the cavities intended for the devices operating at lower pressure, a layer of an absorbent material or getter is also deposited. When the second wafer is joined to the first wafer, for example by glass-frit bonding or another wafer bonding technique, or at a later time with a dedicated step, the getter is thermally activated in order to absorb the non-noble gases (for example nitrogen, oxygen, hydrogen) present in the chamber, reducing pressure. In this manner, sealed chambers with different pressures may be obtained and the respective devices may operate under optimal pressure conditions.

However, even this last solution is not free from limitations. For example, when a particularly high pressure needs to be obtained in one of the chambers, the amount of non-noble gas may saturate the getter; in this case, the pressure target in the chamber may not be achieved. To avoid saturation, it is necessary to increase the area and/or thickness of the getter, resulting in an increase in size and production costs.

Furthermore, during the manufacturing, the getter may be activated prematurely, during the “wafer bonding” steps, before the chambers are completely sealed. In this case, the getter may also absorb gas from the chamber with higher pressure (so-called cross-talk), creating a double drawback: the pressure in the chamber without getter decreases in an undesirable and unpredictable manner; and the probability that getter saturation will occur increases, resulting in the impossibility of correctly reducing the pressure in the chamber with lower pressure.

There is accordingly a need in the art to overcome at least in part the drawbacks of the prior art.

### SUMMARY

According to the present invention, a manufacturing process of a microelectromechanical system and a microelectromechanical system are provided.

### BRIEF DESCRIPTION OF THE DRAWINGS

For a better understanding of the present invention, preferred embodiments are presented, by way of non-limiting example, with reference to the attached drawings, wherein:

FIGS. 1-6 and 8 schematically show cross-sections of a microelectromechanical system, during successive steps of a manufacturing process; and

FIG. 7 schematically shows a top-plan view of a portion of a semiconductive wafer, during a step of the manufacturing process shown in FIG. 6.

### DETAILED DESCRIPTION

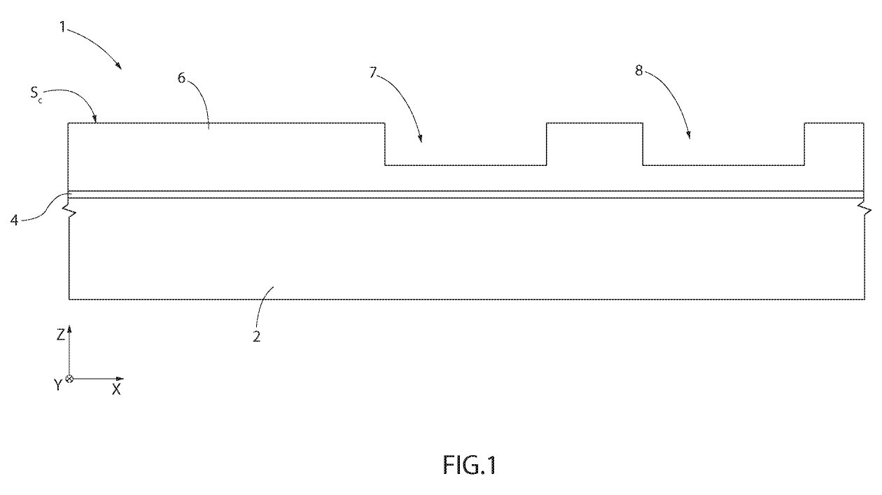

The present manufacturing process is developed starting from a first semiconductive wafer 1, which, as shown in FIG. 1, comprises: a substrate 2 of semiconductor material (for example, silicon); an intermediate dielectric layer 4, formed for example by silicon oxide and arranged above the substrate 2, in direct contact; and a front semiconductive region 6, formed for example by silicon and arranged above the intermediate dielectric layer 4, in direct contact, in such a way that the intermediate dielectric layer 4 is interposed between the front semiconductive region 6 and the substrate 2. FIG. 1 also shows an orthogonal reference system XYZ. The front semiconductive region 6 is delimited at the top by a surface Sc, approximately parallel to the XY plane.

For example, the first semiconductive wafer 1 may be formed by a so-called “silicon on insulator” (SOI) wafer or it may be obtained starting from the substrate 2, by performing a thermal oxidation process, to form the intermediate dielectric layer 4, and a successive silicon deposition, to form the front semiconductive region 6.

As shown again in FIG. 1, an etch process is performed, in a per se known manner, to selectively remove portions of the front semiconductive region 6, in order to form a first and a second cavity 7, 8. The first and second cavities 7, 8 therefore extend within the front semiconductive region 6, starting from the surface Sc, at a distance from the underlying intermediate dielectric layer 4, and do not completely traverse the front semiconductive region 6. Furthermore, the first and second cavities 7, 8 are laterally offset and, although not shown, may have shapes and depths different from each other.

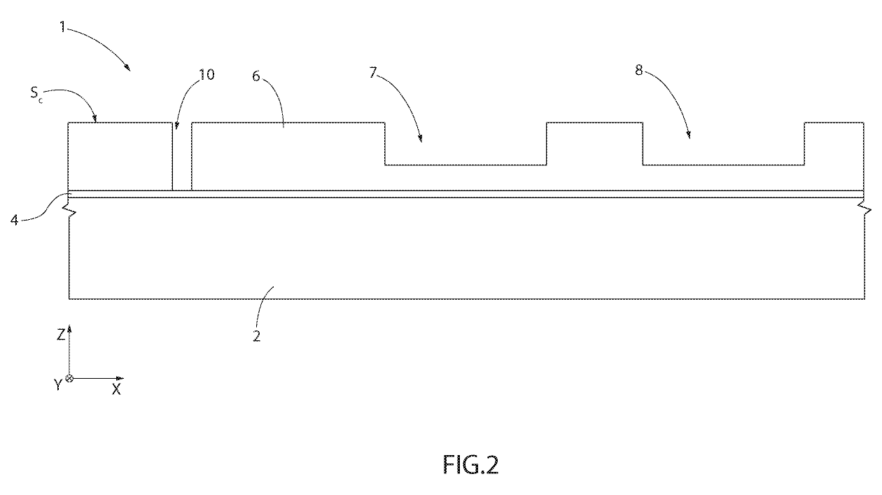

Subsequently, as shown in FIG. 2, an etch process is performed, for example of the dry and/or wet anisotropic type, to selectively remove a portion of the front semiconductive region 6 and form a first channel 10, which extends vertically. The etch process lands on the intermediate dielectric layer 4, in such a way that the first channel 10 extends through the front semiconductive region 6, starting from the surface Sc, until it reaches a corresponding portion of the intermediate dielectric layer 4, which closes at the bottom the first channel 10.

In greater detail, the first channel 10 is laterally offset with respect to the first and second cavities 7, 8. Furthermore, purely by way of example, the first channel 10 may have a cylindrical shape, with a diameter for example greater than or equal to 30 µm. However, variants are possible wherein the first channel 10 has a different shape, with a critical dimension (CD) for example greater than 30 µm.

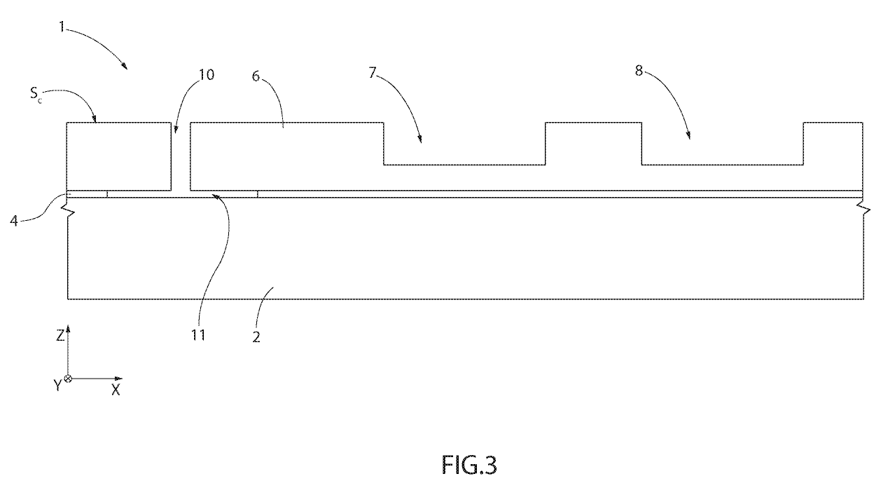

Subsequently, as shown in FIG. 3, a part of the intermediate dielectric layer 4 is selectively removed, including the portion of the intermediate dielectric layer 4 that closes at the bottom the first channel 10; in this manner, an intermediate chamber 11 is formed.

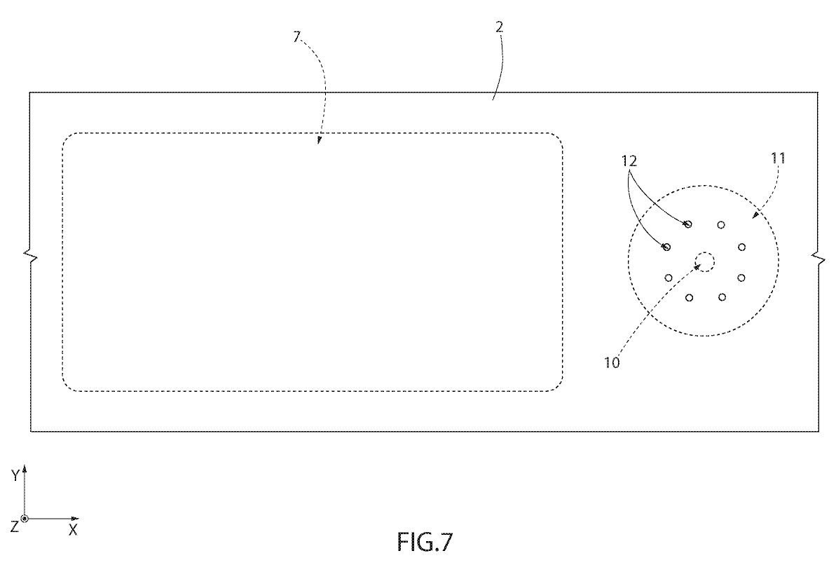

In greater detail, the intermediate chamber 11 is delimited laterally by corresponding portions of the intermediate dielectric layer 4 and is delimited at the bottom by the substrate 2; furthermore, the intermediate chamber 11 is delimited at the top by a corresponding portion of the front semiconductive region 6. The intermediate chamber 11 communicates fluidly with the outside world through the first channel 10. Furthermore, parallel to the XY plane, the intermediate chamber 11 has a greater extension with respect to the extension of the first channel 10, which, without any loss of generality, may be arranged, parallel to the XY plane, in such a way that the intermediate chamber 11 has an approximately symmetrical shape with respect to the first channel 10, as shown for example in FIG. 7, wherein it is assumed that the intermediate chamber 11 has an approximately cylindrical shape. In addition, the intermediate chamber 11 is laterally offset with respect to the first cavity 7, which is interposed, parallel to the X axis, between the intermediate chamber 11 and the second cavity 8. In particular, the first cavity 7 does not even partially superimpose on the intermediate chamber 11.

In even greater detail, the aforementioned selective removal of a part of the intermediate dielectric layer 4 may occur, for example, by an etch with hydrofluoric acid in vapor phase or liquid solution (wet etch).

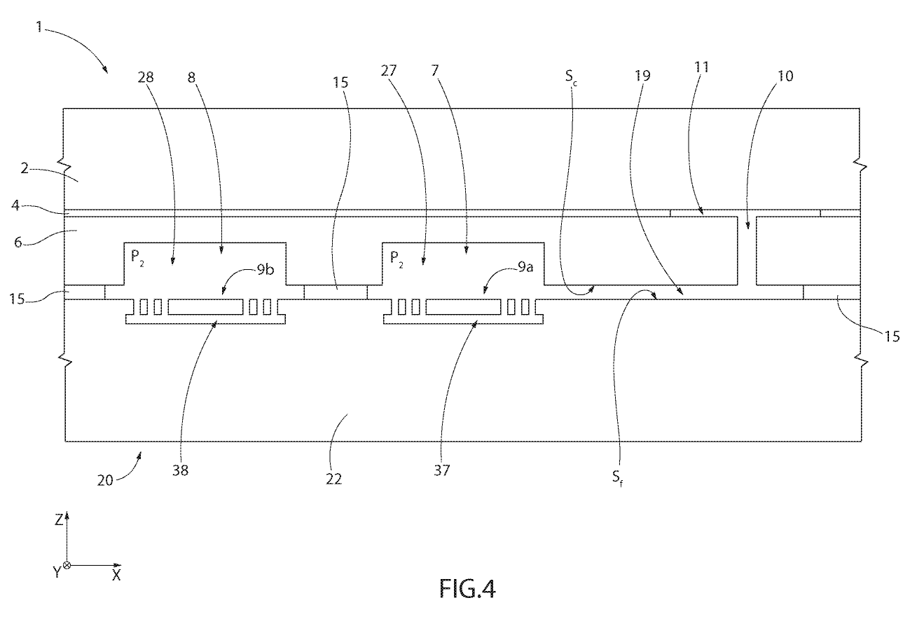

Subsequently, as shown in FIG. 4, the first semiconductive wafer 1 is flipped over and then bonded to a second semiconductive wafer 20, by a bonding structure 15 of a type known per se.

In detail, the second semiconductive wafer 20 comprises a main body 22, which is delimited at the top by a front surface Sf and is formed at least in part by semiconductor material. In this regard, although not shown, the main body 22 may comprise a respective semiconductive substrate, one or more semiconductive regions of silicon or polysilicon, as well as, possibly, dielectric regions. Furthermore, in a manner known per se, in the second semiconductive wafer 20 a first and a second microelectromechanical structure 9a, 9b are present, which are for example suspended above a first recess 37 and, respectively, a second recess 38, that extend in the main body 22 and are laterally offset.

In greater detail, the first cavity 7 and the first recess 37 are coupled to form a first chamber 27, within which the first microelectromechanical structure 9a extends, which forms a first sensor (for example, a gyroscope) and may therefore comprise springs, one or more suspended masses and electrodes (not shown). The second cavity 8 and the second recess 38 are coupled to form a second chamber 28, within which the second microelectromechanical structure 9b extends, which forms a second sensor (for example, an accelerometer) and may therefore comprise springs, one or more suspended masses and electrodes (not shown).

In even greater detail, the bonding between the first and second semiconductive wafers 1, 20 is done in such a way that bonding structure 15 extends between portions of the surface Sc of the front semiconductive region 6 and portions of the front surface Sf of the main body 22. For example, the bonding structure 15 is of the “glass-frit” type or is formed by a metal bonding (for example eutectic AlGe or Au-Au). Furthermore, the bonding structure 15 is such that the second chamber 28 is hermetically sealed; in this regard, the pressure in the second chamber 28 is indicated as the pressure P2 and is equal to the pressure of the environment wherein the bonding between the first and second semiconductive wafers 1, 20 occurs; the value of the pressure P2 may therefore be set and may for example be between 0.01 Bar and 5 Bar.

Furthermore, the bonding between the first and second semiconductive wafers 1, 20 is made in such a way as to form a transversal channel 19 which extends parallel to the XY plane, therefore perpendicular to the first channel 10, and is delimited at the top by the front semiconductive region 6 of the first semiconductive wafer 1 and is delimited at the bottom by the main body 22 of the second semiconductive wafer 20. Furthermore, the transversal channel 19 communicates laterally with the first chamber 27 and is delimited laterally by a portion of the bonding structure 15. In addition, the transversal channel 19 extends parallel to the XY plane in such a way as to communicate with the first channel 10. At this stage of the manufacturing process, the first chamber 27 is also at pressure P2, because the first chamber 27 is coupled to a channel structure 33 that is formed by the transversal channel 19, the first channel 10 and the intermediate chamber 11, but does not communicate fluidically with the outside world.

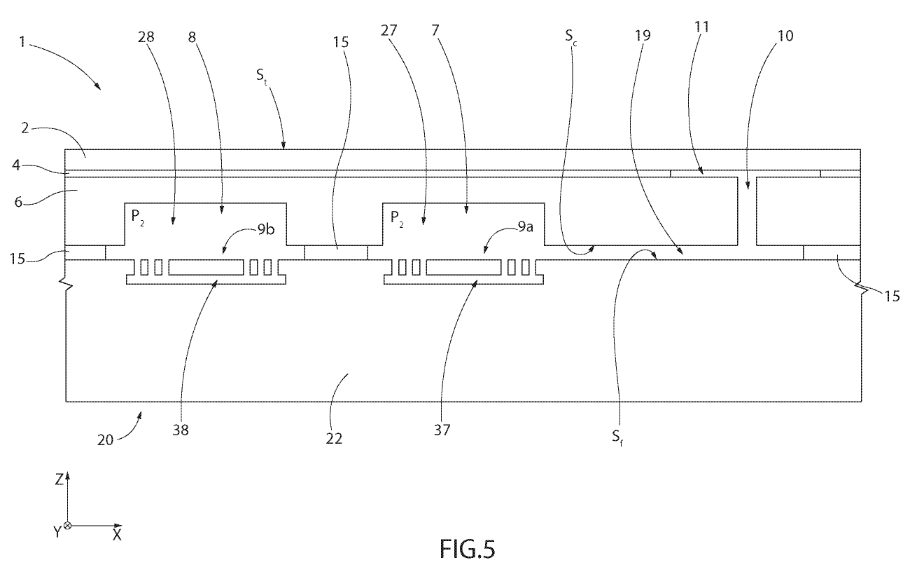

Subsequently, as shown in FIG. 5, a lapping process of the substrate 2 of the first semiconductive wafer 1 is performed (optionally), to reduce the thickness of the substrate 2, for example to a value equal to about 170 µm. Following lapping, the substrate 2 is delimited at the top by a top surface St. Furthermore, as previously explained, the intermediate chamber 11 is laterally spaced from the first chamber 27, as well as from the second chamber 28, in such a way as not to superimpose even partially on the first chamber 27, nor on the second chamber 28.

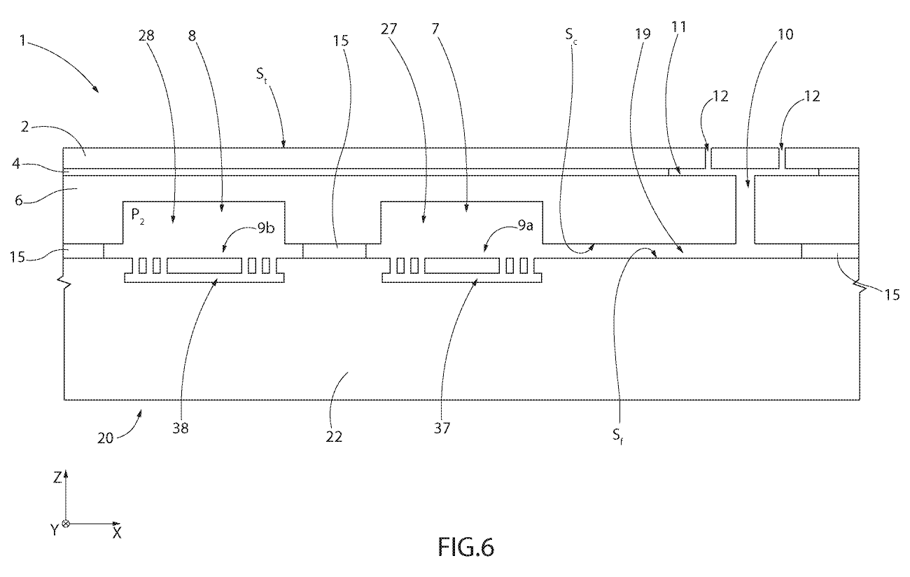

Subsequently, as shown in FIG. 6, a further etch process is performed, for example of the dry or wet type, to selectively remove portions of the substrate 2 that overlie the intermediate chamber 11, to form a plurality of second channels 12.

Each second channel 12 extends vertically between the top surface St and the intermediate chamber 11, to set the intermediate chamber 11 in fluidic communication with the outside world, i.e., with the top surface St.

In greater detail, as shown in FIG. 7 (wherein for simplicity only the first semiconductive wafer 1 is shown), the second channels 12 may approximately have the shape of cylinders, for example approximately equal, and may be arranged laterally offset with respect to the underlying first channel 10, so as not to superimpose on the underlying first channel 10 even partially. Furthermore, the second channels 12 have a critical dimension lower than the critical dimension of the first channel 10, for example lower than 2 µm, to facilitate the successive sealing. In particular, the second channels 12 are arranged, for example, in a symmetrical manner with respect to the first channel 10.

In practice, the first semiconductive wafer 1 functions as a cap. Furthermore, since the second channels 12 are laterally offset with respect to the first chamber 27, as well as to the second chamber 28, both the first and second chambers 27, 28 are overlaid by corresponding portions of substrate 2 that are not traversed by any second channel 12, which improves construction robustness. Furthermore, the etch that causes the formation of the second channels 12 does not require the presence of a landing layer.

Following the formation of the second channels 12, the pressure within the second chamber 27 may vary, based on the pressure present in the outside world, i.e., on the top surface St.

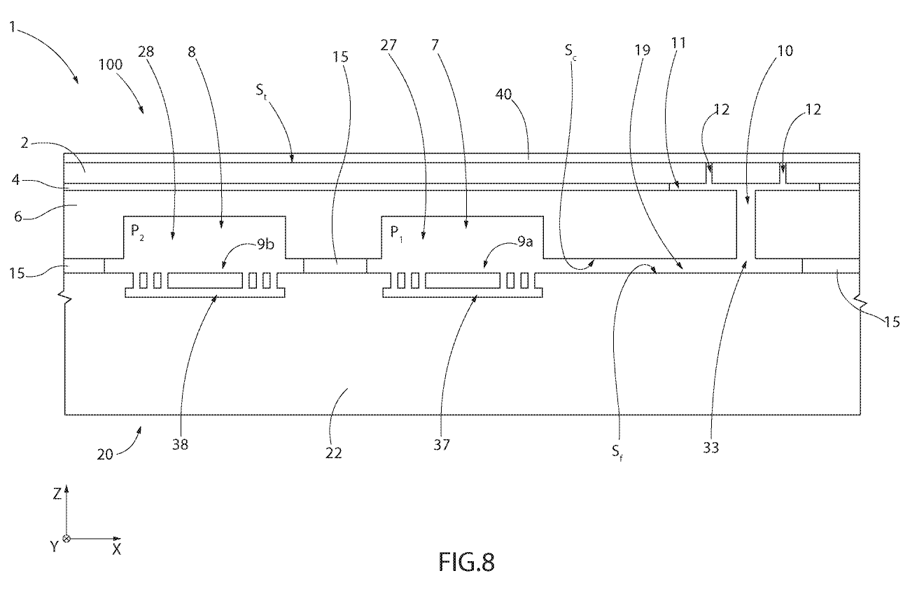

Subsequently, as shown in FIG. 8, a sealing layer 40 is formed on the top surface St of the substrate 2, to hermetically close the second channels 12. In this manner, the environment formed by the first chamber 27 and the channel structure 33 is hermetically closed. The microelectromechanical system thus formed is indicated by 100.

In greater detail, the sealing layer 40 may be formed by a dielectric material, such as, for example, silicon oxide (SiO2), silicon nitride (SiN), or silicon oxynitride (SiON). Furthermore, the sealing layer 40 may be formed by plasma-enhanced chemical vapor deposition (PECVD), for example at a pressure between 1 mBar and 10 mBar and a temperature between 100°C and 450°C, in such a way that, once the environment formed by the first chamber 27 and the channel structure 33 has been sealed, the pressure within this environment, following cooling for example to 25°C, is between 0.5 mBar and 5 mBar. Alternatively, the sealing layer 40 may be formed by performing a chemical vapor deposition (CVD) or a physical vapor deposition (PVD) or a combination of a CVD deposition and a PVD deposition. For example, in case a PVD deposition is performed, it is possible to set that, at the end of the deposition, the pressure within the environment formed by the first chamber 27 and the channel structure 33 is lower than 0.1 mBar.

Regardless of the deposition technique used, once the sealing layer 40 has been formed, the pressure within the environment formed by the first chamber 27 and the channel structure 33 is equal to a pressure P1, which has been set by the process of forming the sealing layer 40 and may be lower than pressure P2 present in the second chamber 28.

Subsequently, the manufacturing process may proceed in a manner known per se and not shown, for example by dicing operations that cause the formation, starting from the first and second semiconductive wafers 1, 20, of corresponding semiconductive bodies coupled to each other.

The advantages that the present manufacturing process affords are clear from the preceding description.

In particular, the present manufacturing process allows for setting different pressures in the chambers of the microelectromechanical system, without the need to use a getter region, therefore in a simple and inexpensive manner. Furthermore, second channels are not present above the first and second chambers, with consequent advantages in terms of robustness, since, conversely, the etch process to form the second channels might cause erosions of portions of the front semiconductive region arranged above the first and second chambers. In addition, the lateral misalignment between the second channels and the first channel allows for reducing the probability of introducing by-products of the etch that allows for forming the second channels into the first chamber.

Finally, it is clear that modifications and variations may be made to what has been described and illustrated herein without thereby departing from the scope of the present invention, as defined in the attached claims.

For example, although in FIG. 8 the sealing layer 40 does not penetrate within the second channels 12, the sealing layer 40 may penetrate at least in part within the second channels 12.

Only one second channel 12 may also be present and/or one or more second channels 12 may be at least partially superimposed on the underlying first channel 10. Both the first channel 10 and the second channels 12 may have different shapes with respect to what has been described.

The mutual arrangement of the first channel 10 and the first and second cavities 7, 8 may vary with respect to what has been described. Furthermore, the order in which the first channel 10, the intermediate chamber 11 and the first and second cavities 7, 8 are formed may vary with respect to what has been described. Furthermore, the order in which the first channel 10, the intermediate chamber 11 and the first and second cavities 7, 8 are formed may vary with respect to what has been described.

The bonding process of the first and second semiconductive wafers 1, 20 may occur in a different manner or with different materials with respect to what has been described.

The pressures P1 and P2 may be in a different relationship with respect to what has been described.

Finally, the first and second sensors may be of a different type with respect to what has been described; furthermore, the shapes of the first and second chambers 27, 28 may also vary with respect to what has been described.

1. A process for manufacturing a microelectromechanical system starting from a first semiconductive wafer comprising a semiconductive substrate, a semiconductive region and a dielectric region interposed between the semiconductive substrate and the semiconductive region, the semiconductive region being delimited by a surface, said process comprising:
forming a first cavity and a second cavity which extend into the semiconductive region starting from the surface and are laterally offset;
forming a first channel which extends through the semiconductive region starting from the surface to a corresponding portion of the dielectric region, wherein said first channel is laterally offset with respect to the first cavity and the second cavity;
successively selectively removing said portion of the dielectric region to form an intermediate chamber which extends between the semiconductive substrate and the semiconductive region and is laterally delimited by corresponding portions of the dielectric region and in communication with the first channel;
mechanically coupling the first semiconductive wafer to a second semiconductive wafer, wherein a first microelectromechanical structure and a second microelectromechanical structure are formed, in such a way that the first cavity and the second cavity form respectively a first chamber and a second chamber, the second chamber being hermetically closed and having therewithin a pressure equal to a second chamber value, the first microelectromechanical structure and the second microelectromechanical structure extending respectively in the first chamber and the second chamber in such a way as to form a transversal channel which is delimited by the semiconductive region and by the second semiconductive wafer and which places the first chamber in communication with the first channel and the intermediate chamber;
forming second channels which extend through the semiconductive substrate to the intermediate chamber to place the first chamber in communication with the outside; and
setting a pressure in the first chamber equal to a first chamber value and hermetically closing the second channels, to hermetically close the first chamber, the transversal channel, the first channel and the intermediate chamber.

2. The manufacturing process according to claim 1, wherein the intermediate chamber is laterally offset with respect to the first cavity and the second cavity; and wherein the second channels are laterally offset with respect to the first chamber and the second chamber.

3. The manufacturing process according to claim 1, wherein the second channels have critical dimensions smaller than a critical dimension of the first channel.

4. The manufacturing process according to claim 1, wherein the second channels are laterally offset with respect to the first channel.

5. The manufacturing process according to claim 1, wherein mechanically coupling the first semiconductive wafer to a second semiconductive wafer comprises forming a bonding structure that laterally delimits part of the second chamber and laterally delimits part of the first chamber and the transversal channel.

6. The manufacturing process according to claim 1, wherein hermetically closing the second channels comprises forming a dielectric sealing layer on the semiconductive substrate.

7. The manufacturing process according to claim 6, wherein hermetically closing comprises performing at least one of a plasma-enhanced chemical vapor deposition, a physical vapor deposition, and a chemical vapor deposition.

8. The manufacturing process according to claim 1, wherein the first chamber value is lower than the second chamber value.

9. The manufacturing process according to claim 1, wherein the second channels are arranged symmetrically with respect to the first channel.

10. The process according to claim 1, wherein the sealing layer comprises a material selected from the group consisting of: silicon oxide, silicon nitride, or silicon oxynitride.

11. The process according to claim 1, wherein the bonding structure is formed by one of: glass-frit bonding, eutectic AlGe bonding, or Au-Au bonding.

12. A microelectromechanical system, comprising:
a first semiconductive body comprising:
a semiconductive substrate, a semiconductive region and a dielectric region interposed between the semiconductive substrate and the semiconductive region, the semiconductive region being delimited by a first surface;
a first cavity and a second cavity extending into the semiconductive region starting from the first surface and which are laterally offset;
a first channel extending through the semiconductive region starting from the first surface, which is laterally offset with respect to the first cavity and the second cavity and communicates with an intermediate chamber, and which extends between the semiconductive substrate and the semiconductive region and is laterally delimited by corresponding portions of the dielectric region;
a second semiconductive body including a first microelectromechanical structure and a second microelectromechanical structure, wherein said second semiconductive body is coupled to the first semiconductive body in such a way that the first cavity and the second cavity form respectively a first chamber and a second chamber;
wherein the second chamber is hermetically closed and has therewithin a pressure equal to a second chamber value;
wherein the first microelectromechanical structure and second microelectromechanical structure extend respectively in the first chamber and the second chamber such that the semiconductive region and the second semiconductive body delimit a transversal channel which puts the first chamber in communication with the first channel and the intermediate chamber;
second channels extending through the semiconductive substrate to the intermediate chamber; and
a dielectric sealing layer arranged on the semiconductive substrate and hermetically closing the second channels,the first chamber, the transversal channel, the first channel and the intermediate chamber, wherein the pressure in the first chamber is equal to a first chamber value.

13. The microelectromechanical system according to claim 12, wherein the intermediate chamber is laterally offset with respect to the first cavity and the second cavity; and wherein the second channels are laterally offset with respect to the first chamber and the second chamber.

14. The microelectromechanical system according to claim 12, wherein the second channels are laterally offset with respect to the first channel.

15. The microelectromechanical system according to claim 12, wherein the first microelectromechanical structure is a gyroscope and the second microelectromechanical structure is an accelerometer.
